(19) United States
(12) Patent Application Publication
(10) Pub. No.: US 2026/0314342 A1
(43) Pub. Date: Oct. 8, 2026

(54) SELECTIVE ETCH OF A STACK WITH A CARBON CONTAINING MASK

(71) Applicant: Lam Research Corporation, Fremont, CA (US)

(72) Inventor: Mingmei WANG, Fremont, CA (US)

(21) Appl. No.: 19/490,271

(22) PCT Filed: Jun. 12, 2024
(86) PCT No.: PCT/US2024/033641

§ 371 Date: Dec. 4, 2025

Related U.S. Application Data
(60) Provisional application No. 63/509,995, filed on Jun. 23, 2023.

(51) Int. Cl. H10P 76/40; H10P 50/00

(52) U.S. Cl. CPC H10P 76/4085; H10P 50/69

(57) ABSTRACT

A method of etching a stack below a carbon containing mask is provided, where the method comprises a plurality of cycles, where each cycle comprises a carbon deposition phase for selectively depositing carbon on the top surface of the carbon containing mask, comprising activating the top surface of the carbon containing mask by bombarding the top surface of the carbon containing mask with ions, flowing a deposition gas comprising a hydrogen source and an organochloride source selected from at least one of carbon tetrachloride (CCl₄) and CₓH_{y}Cl_{z} (where x>0 and z>0), and forming the deposition gas into a plasma to form at least one of radicals and ions of CₙClₘ (where x>0 and z>0) and at least one of radicals and ions of H, which deposit carbon on the carbon containing mask and an etch phase that etches features into the stack.

### CROSS-REFERENCE TO RELATED APPLICATION

This application claims the benefit of priority of U.S. Application No. 63/509,995, filed Jun. 23, 2023, which is incorporated herein by reference for all purposes.

### BACKGROUND

One process frequently employed during the fabrication of semiconductor devices is the formation of a recessed feature in a stack below a carbon containing mask. The stack may be alternating/repeating layers into which the recessed feature is formed, or a thick film of a single layer of material. One example context where such a process may occur is memory applications such as DRAM and NAND. In the manufacturing of some semiconductor devices, metal or other materials may be etched below a carbon containing mask. As the semiconductor industry advances and device dimensions become smaller, such recessed features become increasingly harder to etch in a uniform manner, especially for high aspect ratio features having narrow widths and/or deep depths.

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method of etching recessed features in a stack below a carbon containing mask, wherein the carbon containing mask has a top surface is provided. The method comprises a plurality of cycles, wherein each cycle comprises a carbon deposition phase for selectively depositing carbon on the top surface of the carbon containing mask, comprising activating the top surface of the carbon containing mask by bombarding the top surface of the carbon containing mask with ions, flowing a deposition gas comprising a hydrogen source and an organochloride source selected from at least one of carbon tetrachloride (CCl₄) and CₓH_{y}Cl_{z} (where x>0 and z>0), and forming the deposition gas into a plasma to form at least one of radicals and ions of CₙClₘ (where x>0 and z>0) and at least one of radicals and ions of H, which deposit carbon on the carbon containing mask and an etch phase that etches features into the stack.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 depicts a flow chart describing a method of etching recessed features into a stack below a carbon containing mask according to various embodiments.

FIGS. 2A-2E illustrate a schematic cross-sectional illustration of a stack processed according to some embodiments.

FIG. 3 is a flow chart of a carbon deposition phase.

FIGS. 4A-C is a schematic cross-sectional view of a carbon containing mask processed according to some embodiments.

FIG. 5 shows a semiconductor processing system that may be used in some embodiments.

FIG. 6 illustrates a computer system for implementing a controller used in some embodiments.

In the drawings, like reference numerals are sometimes used to designate like structural elements. It should also be appreciated that the depictions in the figures are diagrammatic and not to scale.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Fabrication of certain semiconductor devices involves etching features into a stack of materials. In various embodiments herein, the stack of materials includes one or more layers of one or more materials below a carbon containing mask. In some embodiments, at least one layer of the stack contains at least one of silicon, germanium, and metal. Silicon containing layers may contain silicon nitride, silicon oxide, silicon carbide, silicon oxy-nitride, silicon oxy-carbide, polysilicon, or silicon germanium. In one example, the stack includes alternating layers of silicon oxide and polysilicon. In some embodiments, the stack comprises an alternating silicon oxide film with silicon nitride films, or single silicon oxide layer, or single silicon layer. In some embodiments, the stack may be a conductive or dielectric layer that may be a metal or silicon containing layer below a carbon containing mask. In some embodiments, the carbon containing mask is a carbon containing at least one of a photoresist, a doped carbon, and an amorphous carbon mask.

The features etched into a stack may be cylinders, trenches, or other recessed features. The aspect ratio of such a feature is defined as the lateral critical dimension divided by the depth. As the aspect ratio of such features continues to increase, several issues arise including (1) insufficient mask selectivity, (2) etch resolution, (3) twisting of the features, (4) non-circularity of the features, (5) aspect-ratio dependent etch rate, (6) bowing etch profile, and (7) low etch rate.

Insufficient mask selectivity is problematic when the etch process removes an excessive amount of the carbon containing mask, so that no mask remains at the end of the process, or when the amount of mask remaining is insufficient to properly transfer the pattern from the mask to the stack. One common result of insufficient mask selectivity is the degradation of the feature profile near the top of the recessed features. In order to compensate for insufficient mask selectivity, a thicker mask may be formed. However, a thicker mask results in lower mask resolution and an overall higher aspect ratio, which causes more issues during the etching of both mask and underlayer materials.

Twisting refers to random deviations between the intended bottom locations of the features and the actual final bottom locations of the features (e.g., with the final location of a feature corresponding to the position of the bottom of the feature after the feature is etched). For instance, in some cases, it is intended that cylindrical features are etched in a regular array. When some or all features randomly deviate at the bottom away from this array, they are understood to have twisted.

Non-circularity of the features refers to deviations of the bottom hole shape away from a circular hole shape. This issue is relevant when etching circular features such as cylinders, where it is desired that the bottoms of the recessed features are circular. When the bottom hole shape deviates away from a circular shape, it often forms a shape closer to an ellipse, triangle, or irregular polygon. In many cases, these non-circular shapes are not desirable.

Aspect-ratio dependent etch rate refers to an issue where the etch rate slows down as the aspect ratio of the features increases. In other words, as the features are etched further into the stack, the etching process slows down. This issue is problematic because it can lead to low throughput and associated high processing costs.

Bowing etch profile refers to the tendency for the features to etch laterally in the stack such that the final profile bows outwards excessively somewhere along the depth of the features. In other words, the actual maximum critical dimension of the features exceeds the desired maximum critical dimension of the features, which can compromise the integrity of the structures being formed or limit the electrical performance of the final devices.

Low etch rate refers to an etch rate that is slower than desired for a particular application. Low etch rate is problematic because it leads to long etch times, reduced throughput, and high processing costs.

Unfortunately, techniques that improve some of these issues, such as insufficient mask selectivity, often make other issues worse. As such, these issues are balanced against one another when designing an etching operation. For example, conventional commercially practiced dielectric etch processes often result in substantial bowing. Previously, such tradeoffs have been difficult to avoid.

The techniques described herein may be used to etch recessed features into a stack below a carbon containing mask without some or all of the issues identified above. In other words, the disclosed techniques may be used to etch recessed features into a stack below a carbon containing mask with a high stack to carbon containing mask selectivity and with reduced mask twisting, reasonably circular features, an acceptable degree of aspect ratio dependent etch rate, acceptable bowing, and sufficient etch rate.

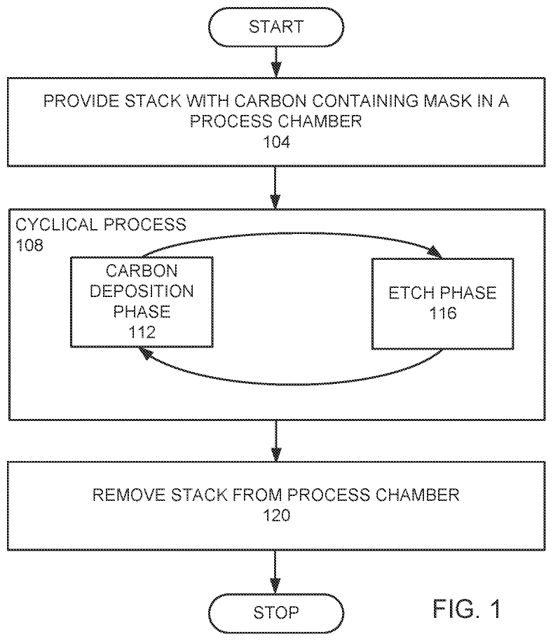

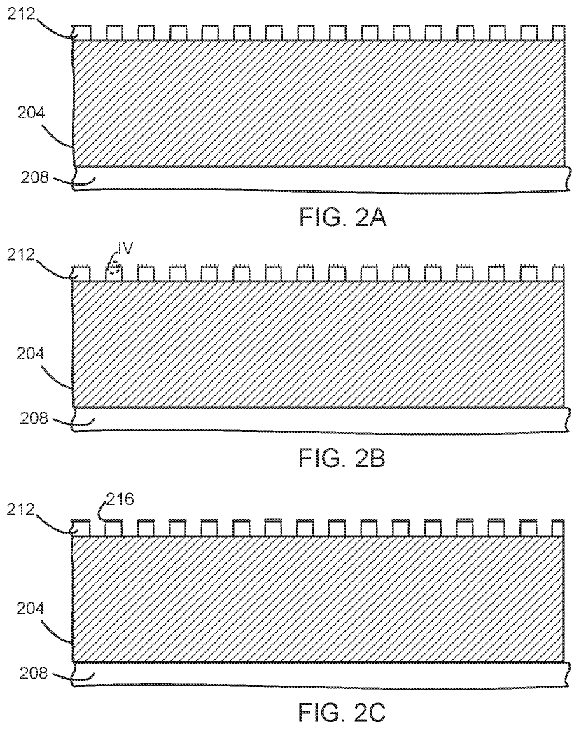

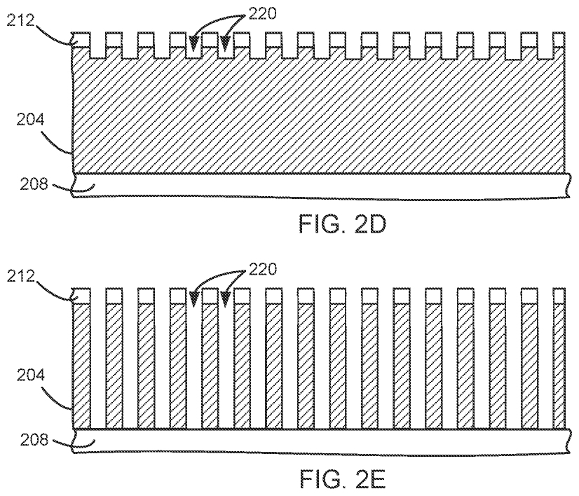

To facilitate understanding, FIG. 1 is a high level flow chart of a method that may be used in some embodiments. A stack with a carbon containing mask is provided in a process chamber (step 104). FIG. 2A is a schematic cross-sectional view of a stack 204 that may be processed according to some embodiments, where the stack is under a carbon containing mask 212, such as an organic mask, one example of which would be an amorphous carbon mask. The amorphous carbon mask may also include some amount of hydrogen and/or oxygen. In some embodiments, the stack 204 may be formed over a substrate 208. In some embodiments, the stack 204 may comprise a silicon containing layer, such as silicon oxide, silicon nitride, or silicon. In some embodiments, the stack 204 may be a metal containing layer such as a pure or alloy conductive metal layer or a metal nitride or metal oxide. In some embodiments, the stack 204 may comprise a germanium containing layer. In some embodiments, the stack is a single bulk layer. In some embodiments, the stack is a plurality of layers. In some embodiments, the stack is a plurality of bilayers, trilayers, or more multiple layers.

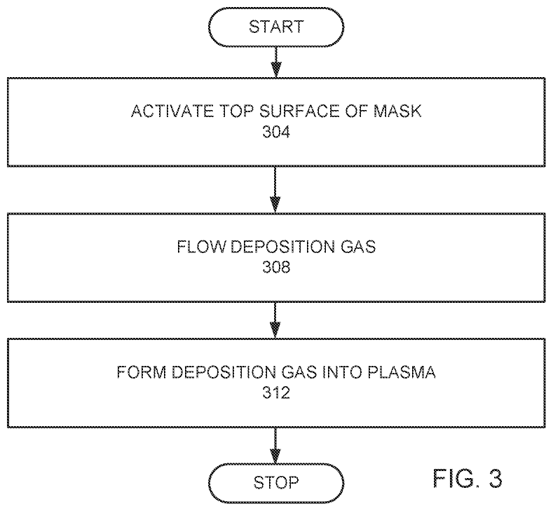

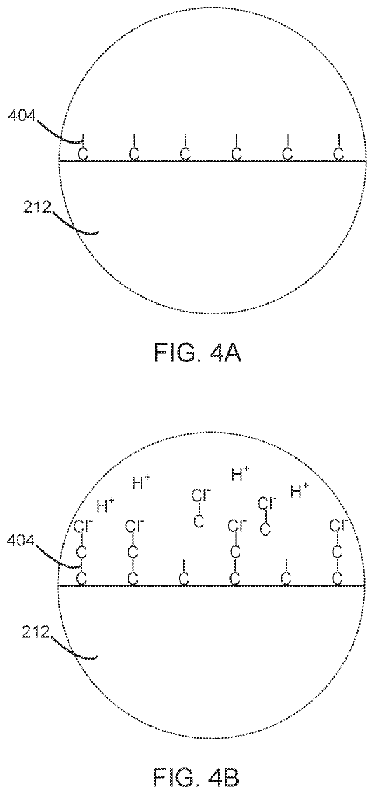

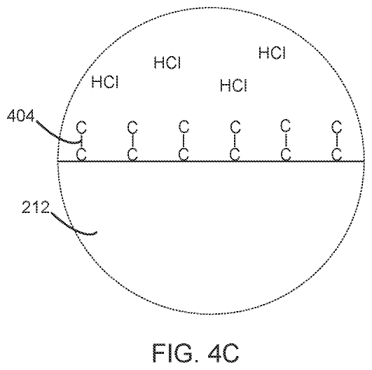

A cyclical process is provided (step 108) for etching the stack 204 comprising a plurality of cycles wherein each cycle comprises a carbon deposition phase (step 112) and an etch phase (step 116). FIG. 3 is a high level flow chart of the carbon deposition phase (step 112) used in some embodiments. First, the top surface of the carbon containing mask 212 is activated by bombarding the top surface of the carbon containing mask with ions (step 304). Ion bombardment of the top surface is defined by providing ions that are directed to the top surface by a bias, where the directed ions have a sufficient energy to activate the top surface. The bias may be used to help provide the sufficient energy to the ions. In some embodiments, the bombardment is provided by high energy ions. In some embodiments, the ions are at least one of helium ions and argon ions. In some embodiments, a bias in the range of 0 Watts (W) to 100 kilowatts (kW) is provided to accelerate ions toward the top surfaces of the carbon containing mask 212. In some embodiments, a bias in the range of 100 W to 1 kW is provided. In some embodiments, the bombarding ions create dangling carbon bonds. FIG. 2B is a schematic cross-sectional view of a stack 204 after the top surface of the carbon containing mask 212 has been activated. FIG. 4A is an enlarged view of Region IV, shown in FIG. 2B. FIG. 4A schematically illustrates how the carbon atoms C forming the top surface of the carbon containing mask 212 have dangling bonds 404 caused by the bombardment.

After activating the mask (step 304), a deposition gas is flowed (step 308). In some embodiments, the deposition gas comprises a hydrogen source and an organochloride source selected from the group consisting of carbon tetrachloride (CCl₄), CₓH_{y}Cl_{z} (where x>0 and z>0), and combinations thereof. Particular examples of CₓH_{y}Cl_{z} materials include but are not limited to, chloroform (CHCl₃), chloromethane (CH₃Cl), and methylene chloride (CH₂Cl₂). In some cases, C₂H_{y}Cl_{z} may be used. In various embodiments, the organochloride source does not include fluorine or other non-chlorine halogens. An example of a hydrogen source is hydrogen gas (H₂). Although a hydrofluorocarbon may provide some hydrogen, a hydrofluorocarbon does not provide enough hydrogen to be a hydrogen source. Instead, hydrogen from a hydrogen source, such as hydrogen gas would also be needed to provide hydrogen if the deposition gas has a hydrofluorocarbon. In some embodiments, the hydrogen source has a molar hydrogen to molar carbon ratio of at least 1:1. In some embodiments, the hydrogen source has a molar hydrogen to molar carbon ratio of at least 3:1. In some embodiments, the hydrogen source is at least one of methane (CH₄), ethylene (C₂H₄), ethane (C₂H₆), benzene (C₆H₆), and chloromethane (CH₃Cl). In some embodiments, the deposition gas is fluorine free, since the deposition phase deposits on top of the carbon containing mask 212 without etching.

The deposition gas is formed into a plasma (step 312) by providing RF power. In some embodiments, the plasma is a capacitively coupled plasma or an inductively coupled plasma. The plasma in various embodiments may be generated at a radio frequency (RF) power between about 5-200 kilowatts (kW), for example between about 10-100 kW, or between about 10-65 kW in some embodiments. In some cases, a dual-frequency RF may be used to generate the plasma. Thus, the RF power may be provided at two or more frequency components, for example, a first frequency component at about 400 kilohertz (kHz) and a second frequency component at about 60 megahertz (MHz). Different powers may be provided at each frequency component. For instance, the first frequency component (e.g., about 400 kHz) may be provided at a power between about 10-65 kW, and the second frequency component (e.g., about 60 MHz) may be provided at a different power, for example between about 0.5-8 kW. In some embodiments, the first frequency component (e.g., about 400 kHz) may be provided at a power higher than 65 kW. These power levels assume that the RF power is delivered to a single 300 millimeter (mm) wafer. The power levels can be scaled linearly based on substrate area for additional substrates and/or substrates of other sizes (thereby maintaining a uniform power density delivered to the substrate). In other cases, three-frequency RF power may be used to generate the plasma. In some cases, the applied RF power may be pulsed at repetition rates of 1-50,000 Hz. The RF power may be pulsed between two non-zero values (e.g., between higher power and lower power states) or between zero and a non-zero value (e.g., between off and on states). Where the RF power is pulsed between two non-zero values, the powers mentioned above may relate to the higher power state, and the lower power state may correspond to an RF power of about 4 kW or lower. A pulsing duty cycle may be in the range of 5-60%. The pulsing may be at a repetition rate in the range of 100 Hz to 20 kHz. The maximum ion energy at the substrate may be relatively high, for example between about 1-10 kilovolts (kV). The maximum ion energy is determined by the applied RF power in combination with the details of RF excitation frequencies, electrode sizes, electrode placement, chamber geometry, and plasma interactions.

The plasma forms radicals and/or ions of CₙClₘ (where n>0 and m >0) and radicals and/or ions of H, such as CCl⁺ and H⁺. In the specification and claims, radicals are defined as neutral reactive molecules or atoms. In some embodiments, a remote plasma may be used so that only radicals are provided. In some embodiments, ion beams are used so that only ions are provided. The ions on CCl⁺ or radials of CₙClₘ form a carbon bond with the dangling bonds 404 of carbon, as shown in FIG. 4B. The H⁺ ions in the plasma or radicals of H remove the Cl⁻ ions from the bonded CCl⁺ leaving a bonded carbon atom and a volatilized HCl byproduct, as shown in FIG. 4C. In some embodiments, a monolayer of carbon is deposited. In some embodiments, more than a monolayer of carbon is deposited. In some embodiments, less than a monolayer of carbon is deposited. In other embodiments, other radicals or ions of CₓCl_{y} may also be formed in the plasma. FIG. 2C is a schematic cross-sectional view of a stack 204 after the carbon deposition phase (step 112) deposits a carbon containing layer 216. The drawings are not to scale in order to better facilitate understanding. In some embodiments, the carbon deposition may provide some deposition on the sidewalls of features. In some embodiments, the carbon deposition phase is able to selectively deposit carbon on the top surface of the carbon containing mask with respect to sidewalls of the features at a ratio of greater than 5:1. In some embodiments, the carbon deposition phase is able to selectively deposit carbon on the top surface of the carbon containing mask with respect to sidewalls of the features at a ratio of greater than 10:1.

In some embodiments, the activating step (step 304), the flowing of the deposition gas (step 308), and the forming the deposition gas into a plasma (step 312) of the carbon deposition phase (step 112) are performed simultaneously. In such embodiments, the ions may be helium ions, argon ions, or positive ions from the plasma formed from the deposition gas. In some embodiments, the ions are at least one of CₓF_{y}⁺, NFₓ⁺, and CₓH_{y}F_{z}⁺. In some embodiments, a pulsed or continuous bias is provided during the carbon deposition phase (step 112). In some embodiments, at least two of the activating (step 304), the flowing of the deposition gas (step 308), and the forming the deposition gas into a plasma (step 312) of the carbon deposition phase (step 112) overlap in time.

After the carbon deposition phase (step 112), an etch phase is provided. The recipe used during the etch phase is dependent on the material or materials that are to be etched in the stack. In some embodiments, the etch phase selectively etches the stack 204 with respect to the carbon containing mask 212. In some embodiments, the etch phase selectively etches the stack 204 with respect to the carbon containing mask 212 with a selectivity greater than 3:1. In some embodiments, the etch phase selectively etches the stack 204 with respect to the carbon containing mask 212 with a selectivity greater than 5:1. In some embodiments, the etch phase comprises providing an etch gas and forming the etch gas into a plasma. In some embodiments, in order to be able to selectivity etch the stack with respect to the carbon containing mask, the etch gas has a low concentration of oxygen or is oxygen free. In some embodiments, the etch gas comprises a fluorine containing component. In some embodiments, the low concentration of oxygen is less than 5% oxygen by the number of moles with respect to the total number of moles of the etch gas.

FIG. 2D is a schematic cross-sectional view of the stack 204 after etch features 220 have been partially etched into the stack 204. In some embodiments, the carbon containing layer 216 (shown in FIG. 2C) is completely etched away. In some embodiments, the carbon containing layer 216 is partially etched away. In some embodiments, the carbon containing layer 216 and some of the carbon containing mask 212 are etched away. Embodiments where none of the carbon containing mask 212 is etched away during the etch phase provide an almost infinite etch selectivity by etching features in the stack without etching away any of the carbon containing mask 212.

The cycle of providing a carbon deposition phase (step 112) and the etch phase (step 116) is repeated a plurality of times until the etch features 220 are completed. FIG. 2E is a schematic cross-sectional view of the stack 204 after the etch features 220 are completed. After the etch is completed, the stack 204 is removed from the process chamber (step 120).

By providing a cyclical process with a phase that selectively deposits on tops of the carbon containing mask 212 an etch process with close to an infinite selectivity is provided. The near infinite selectivity allows for thinner carbon containing masks allowing for an increased etch resolution. In some embodiments, the carbon deposition phase is kept separate from the etch phase by providing the carbon deposition phase at a different time than the etch phase.

Since the carbon deposition phase is separate from the etch phase, so that the carbon deposition phase does not overlap with the etch phase, the etch phase parameters may be independently adjusted to reduce bowing, reduced twisting of the features, reduced non-circularity of the features, the aspect-ratio dependent etch rate, and the etch rate. By providing a plurality of cycles instead of one cycle allows for the deposition of a thin carbon layer on the top surface of the carbon containing mask instead of a single thick deposition. A single thick deposition would cause reduced resolution, whereas a thin deposition for each cycle provides an increased resolution. In some embodiments, at least ten cycles are provided. In some embodiments, at least 100 cycles are provided. In some embodiments, each deposition cycle deposits a layer with a thickness of 5 to 10 nm.

One application for the disclosed methods is in the context of forming a vertical “not and” (NAND) device. In this case, the material into which the feature is etched may have a repeating layered structure. For instance, the material may include alternating layers of silicon oxide and silicon nitride. In other embodiments, the stack may comprise alternating layers of silicon oxide and polysilicon. The alternating layers form pairs or repeating groups of materials. In various cases, the number of pairs or repeating groups may be between about 10-500 (e.g., between about 20-1000 individual layers). The feature etched into the stack of layers may have a depth between about 2-15 μm, for example between about 5-9 μm. The feature may have a width between about 40-450 nm, for example between about 50-100 nm or between about 40-85 nm. In some embodiments, the features have a width of less than 100 nm. In some embodiments, the features have a width of less than 85 nm.

As used herein, “high aspect ratio” as applied to features in a substrate refers to aspect ratios on the order of approximately 60:1 or higher. More preferably, this range may include ratios greater than 100:1, 120:1, 140:1, etc., or higher. However, the processes described herein may be beneficial for lower aspect ratios, such as 30:1, or 10:1.

The dimensional/parametric details provided herein, such as high aspect ratio, thickness, width, depth, etc., are for example and illustration only. Based on the disclosure described herein, it should be understood that varying dimensions/parameters may also be applicable or used.

### Apparatus

The various hardware and method embodiments described above may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, e.g., a substrate having a silicon containing film formed thereon, using a spin-on or spray-on tool; (2) curing of photoresist using a hot plate or furnace or other suitable curing tool; (3) exposing the photoresist to visible or ultraviolet (UV) or x-ray light with a tool such as a wafer stepper; (4) developing the resist so as to selectively remove the resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, 300 mm, or 450 mm. The above detailed description assumes the embodiments are implemented on a wafer. However, the embodiments are not so limited. The workpiece may be of various shapes, sizes, and materials. In addition to semiconductor wafers, other work pieces that may take advantage of the disclosed embodiments include various articles such as printed circuit boards, magnetic recording media, magnetic recording sensors, mirrors, optical elements, micro-mechanical devices, and the like.

Unless otherwise defined for a particular parameter, the terms “about” and “approximately” as used herein are intended to mean ±10% with respect to a relevant value.

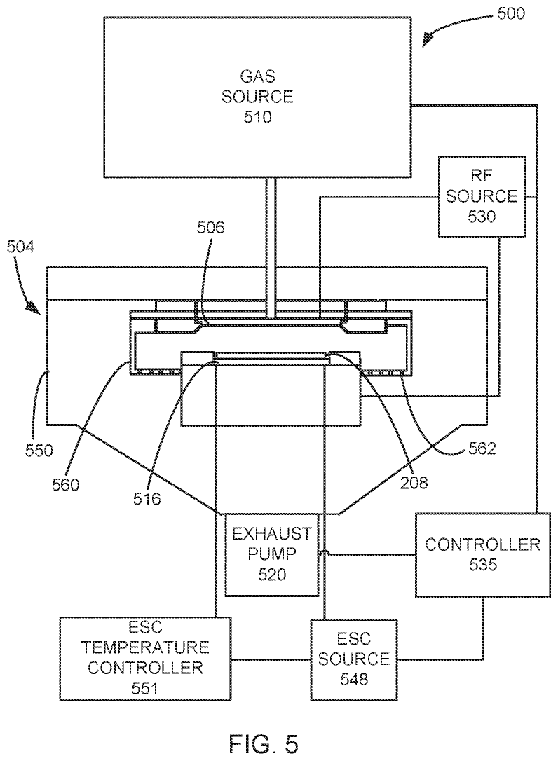

FIG. 5 is a schematic view of a plasma processing chamber 500 for plasma processing substrates, in an embodiment. In one or more embodiments, the plasma processing chamber 500 comprises a gas distribution plate 506 providing a gas inlet and an electrostatic chuck (ESC) 516, within a plasma processing chamber 504, enclosed by a chamber wall 550. Within the plasma processing chamber 504, the substrate 208 is positioned on top of the ESC 516. The ESC 516 may provide a bias from an ESC power source 548. A gas source 510 is connected to the plasma processing chamber 504 through the gas distribution plate 506. An ESC temperature controller 551 is connected to the ESC 516 and provides temperature control of the ESC 516. A radio frequency (RF) power source 530 provides RF power to the ESC 516 and an upper electrode. In this embodiment, the upper electrode is the gas distribution plate 506. In a preferred embodiment, 400 kilohertz (kHz), 13.56 megahertz (MHz), 1 MHz, 2 MHz, 60 MHz, and/or optionally, 27 MHz power sources make up the RF power source 530 and the ESC power source 548 to provide RF power at RF frequencies. A controller 535 is controllably connected to the RF power source 530, the ESC power source 548, an exhaust pump 520, and the gas source 510. A high flow liner 560 is a liner within the plasma processing chamber 504, which confines gas from the gas source and has slots 562. The slots 562 maintain a controlled flow of gas to pass from the gas source 510 to the exhaust pump 520. An example of such a plasma processing chamber is the Flex® etch system manufactured by Lam Research Corporation of Fremont, CA. The process chamber can be a CCP (capacitively coupled plasma) reactor or an ICP (inductively coupled plasma) reactor.

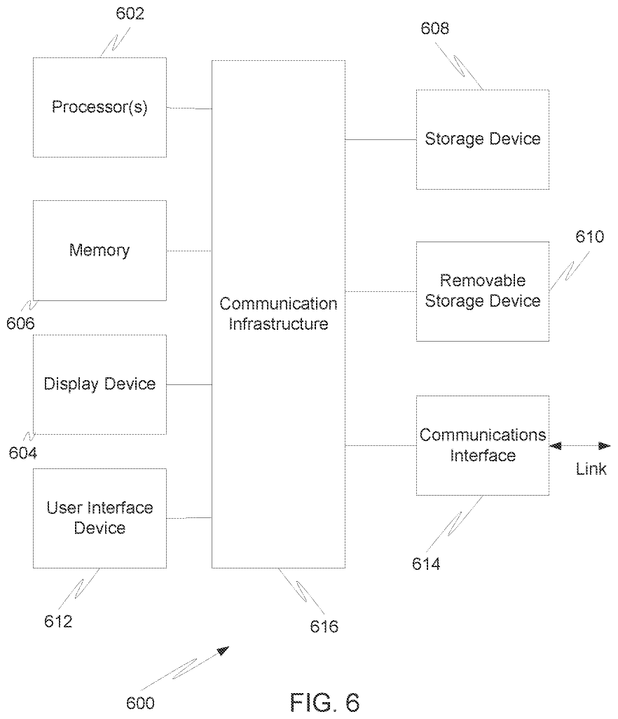

FIG. 6 is a high level block diagram illustrating a computer system 600 for implementing the controller 535 used in embodiments of the present inventions. The computer system may have many physical forms ranging from an integrated circuit, a printed circuit board, and a small handheld device up to a huge supercomputer. The computer system 600 may include one or more processors 602 and further can include an electronic display device 604 (for displaying graphics, text, and other data), a main memory 606 (e.g., random access memory (RAM)), storage device 608 (e.g., hard disk drive), removable storage device 610 (e.g., optical disk drive), user interface devices 612 (e.g., keyboards, touch screens, keypads, mice or other pointing devices, etc.), and/or a communication interface 614 (e.g., wireless network interface). The communication interface 614 may allow software and/or data to be transferred between the computer system 600 and external devices via a link. The system may also include a communications infrastructure 616 (e.g., a communications bus, cross-over bar, or network) to which the aforementioned devices/modules may be connected.

Information transferred via communications interface 614 may be in the form of signals such as electronic, electromagnetic, optical, or other signals capable of being received by communications interface 614, via a communication link that carries signals and may be implemented using wire or cable, fiber optics, a phone line, a cellular phone link, a radio frequency link, and/or other communication channels. With such a communications interface, it is contemplated that the one or more processors 602 might receive information from a network or might output information to the network in the course of performing the above-described method steps. Furthermore, method embodiments may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

It is to be understood that the configurations and/or approaches described herein are exemplary in nature and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed. Certain references have been incorporated by reference herein. It is understood that any disclaimers or disavowals made in such references do not necessarily apply to the embodiments described herein. Similarly, any features described as necessary in such references may be omitted in the embodiments herein. The subject matter of the present disclosure includes all novel and nonobvious combinations and sub-combinations of the various processes, systems and configurations, and other features, functions, acts, and/or properties disclosed herein, as well as any and all equivalents thereof.

### Conclusion

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method of etching recessed features in a stack below a carbon containing mask, wherein the carbon containing mask has a top surface, the method comprising a plurality of cycles, wherein each cycle comprises:
a. a carbon deposition phase for selectively depositing carbon on the top surface of the carbon containing mask, comprising:
i. activating the top surface of the carbon containing mask by bombarding the top surface of the carbon containing mask with ions;
ii. flowing a deposition gas comprising a hydrogen source and an organochloride source selected from at least one of carbon tetrachloride (CCl₄) and CₓH_{y}Cl_{z} (where x>0 and z>0); and
iii. forming the deposition gas into a plasma to form at least one of radicals and ions of CₙClₘ (where x>0 and z>0) and at least one of radicals and ions of H, which deposit carbon on the carbon containing mask; and
b. an etch phase that etches features into the stack.

2. The method of claim 1, wherein the hydrogen source comprises hydrogen gas.

3. The method of claim 1, wherein the at least one of radicals and ions of CₙClₘ form carbon carbon bonds with the carbon containing mask and the at least one of radicals and ions of H remove chlorine from CₙClₘ bonded to the carbon containing mask in a form of an HCl byproduct.

4. The method of claim 1, wherein the carbon deposition phase is fluorine free.

5. The method of claim 4, wherein the etch phase uses a fluorine containing component.

6. The method of claim 1, wherein the carbon deposition phase and the etch phase are separate, occurring at different times.

7. The method, as recited in claim 6, wherein the carbon deposition phase and etch phase do not overlap.

8. The method of claim 1, wherein the carbon containing mask is at least one of amorphous carbon, doped carbon, and photoresist.

9. The method of claim 1, the carbon deposition phase selectively deposits on the top surface of the carbon containing mask with respect to sidewalls of features at a ratio of greater than 5:1.

10. The method of claim 1, wherein the organochloride source is at least one of CCl₄, CHCl₃, CH₃Cl, CH₂Cl₂, and C₂H₂Cl₂.

11. The method of claim 1, wherein the stack comprises at least one of a silicon containing layer, a metal containing layer, and a germanium containing layer.

12. The method of claim 1, wherein the forming the deposition gas into a plasma comprises providing RF power at one or more RF frequencies to provide energy for forming the deposition gas into a plasma.

13. The method of claim 1, wherein steps i, ii, and iii are performed sequentially.

14. The method of claim 1, wherein steps i, ii, and iii are performed simultaneously.

15. The method of claim 1, wherein at least two of the steps i, ii, and iii overlap.
